(19) United States
(12) Patent Application Publication
(10) Pub. No.: US 2013/0338945 A1
(43) Pub. Date: Dec. 19, 2013

(54) Outage Scope Analysis for Electrical Distribution Systems

(71) Applicants: Xiaoming Feng, Cary, NC (US); Fang Yang, Raleigh, NC (US); William Peterson, Fulshear, TX (US)

(72) Inventors: Xiaoming Feng, Cary, NC (US); Fang Yang, Raleigh, NC (US); William Peterson, Fulshear, TX (US)

(73) Assignee: ABB RESEARCH LTD., Zurich (CH)

(21) Appl. No.: 13/495,272

(22) Filed: Jun. 13, 2012

(51) Int. Cl. G01R 31/02; G06F 19/00

(52) U.S. Cl. 702/58

(57) ABSTRACT

Outage scope for an electrical distribution system is estimated by generating downstream outage prediction information indicating whether any service area protected by one of the terminal protective devices of the electrical distribution system likely has a power outage based on reported outage information. Upstream outage prediction information is generated which indicates whether any service area protected by one of the non-terminal protective devices of the electrical distribution system likely has a power outage based on the downstream outage prediction information. Each protective device is predicted to be in an open or closed state based on the downstream and upstream outage prediction information so that more than one open protective device can be identified when more than one fault occurs in different parts of the electrical distribution system.

### TECHNICAL FIELD

The instant application relates to electrical distribution systems, and more particularly to outage scope analysis for electrical distribution systems.

### BACKGROUND

Electrical distribution systems can be implemented as radial, loop or network type systems. The distribution circuits are arranged and interconnected to a substation in different ways depending on the type of system configuration. However for each type of distribution system configuration, the distribution circuits (commonly referred to as feeders and lateral feeders) distribute power delivered from the substation to loads. The loads are connected to the distribution network through service transformers.

Protective devices are used to sectionalize the distribution circuits of an electrical distribution system. For example, each distribution circuits is typically connected to the distribution system through a circuit breaker, recloser or fuse depending on where the distribution circuit is in the network. Each protective device of the electrical distribution system isolates the corresponding distribution circuit from the remainder of the electrical distribution system in the event of a detected fault.

Various types of faults can occur in an electrical distribution system, some of which, permanent faults, result in power outages, i.e., the loss of electric power service to customers. For example, a short circuit fault causes the protective device upstream of the fault to open. When opened, the protective device isolates the short circuit fault. Customers downstream of the opened protective device become de-energized. An open conductor fault in a radial distribution system similarly causes the downstream customers to experience a power outage.

When a fault causes a circuit breaker or recloser to open, the status change of that protective device is typically communicated to the utility control center via SCADA (supervisory control and data acquisition) or other communication means. However when a fault occurs on any distribution circuit connected with a fuse to one or more service transformers, the fuse burns out to isolate the fault and the nearest upstream circuit breaker or recloser does not open, i.e., it remains closed. In addition, no protective device opens responsive to an open conductor fault as there is no short circuit current. Such fault situations conventionally result in no status change for circuit breakers or reclosers included in an electrical distribution system. Instead, the traditional process for the control center in obtaining outage information is through trouble calls placed by affected customers.

After a fault occurs, the outage scope and outage source is estimated before a crew is dispatched to conduct circuit reparation and service restoration to the affected customers. Sometimes this estimation is wrong. For example, a wire may be down below a protective device. The outage engine only estimates to the protective devices and therefore cannot identify the down wire. This condition is found when the field crew arrives.

The term ‘outage scope’ as used herein refers to the service area affected by the fault and the term ‘outage source’ refers to the protective device which opened in response to the fault. The estimation of both outage scope and outage source commonly is referred to as outage analysis, which is a fundamental function of an outage management system (OMS) for a power distribution system. Fast and accurate outage analysis reduces outage duration and improves customer satisfaction. Outage analysis also determines how efficiently repair crews are utilized to perform fault reparation and service restoration tasks.

Due to the very limited real time SCADA information available in a power distribution system, outage analysis conventionally relies on customer phone calls made to the utility company in the event of a power outage as the main information source for such analysis. This process can be quite slow because many customers do not typically call to report an outage, and those who do report an outage often wait a relatively long period of time to report the outage. With the wide deployment of AMR (automatic meter reading) and AMI (advanced metering infrastructure) technologies in power distribution systems, more timely outage information is available from smart meters, such as the so-called last-gasp of the meter. Smart meter reporting enables the control center to be notified more quickly of an outage occurrence.

However, conventional outage analysis methods still estimate the outage scope and outage source by upstream tracing of trouble call locations and identifying the first common protective device covering all trouble call locations. This protective device is identified as the device which most likely opened in response to the fault. A repair crew is then dispatched to the protective device for performing fault reparation and service restoration tasks. Such an outage analysis technique is efficient for single-outage situations, but is rendered unreliable when multiple outages occur. If multiple outages occur within a short time span in different parts of an electrical distribution system, such as during a major storm, the conventional strategy to identify a single open protective device common to all affected service areas unnecessarily enlarges the outage scope and provides inaccurate outage scope and source information. It is unlikely only a single protective device opened in response to multiple outages in different parts of the distribution system. Instead, a more likely scenario involves several protective devices covering smaller service areas opening in response to the different faults instead of a single protective device opening further upstream, which covers a larger service area. As such, a more reliable, robust and exact solution is needed to support both single and multiple outage scenarios in an electrical distribution system.

### SUMMARY

According to the embodiments described herein, outage scope analysis is implemented for an electrical distribution system which includes a plurality of distribution circuits for distributing power to a plurality of loads. A plurality of protective devices are provided throughout the electrical distribution system for isolating one or more of the distribution circuits from the remainder of the electrical distribution system in response to one or more faults. Some of the protective devices are terminal protective devices in that no other protective device is downstream of the terminal protective devices, i.e., there is no other protective device between a terminal protective device and the loads protected by that terminal protective device. The remainder of the protective devices are non-terminal protective devices meaning that one or more other protective devices are downstream of the non-terminal protective devices. The outage management embodiments described herein reduce restoration time, reduce outage duration and improve overall system reliability.

According to an embodiment of a method of estimating outage scope for the electrical distribution system, the method comprises: generating downstream outage prediction information indicating whether any service area protected by one of the terminal protective devices likely has a power outage based on reported outage information; generating upstream outage prediction information indicating whether any service area protected by one of the non-terminal protective devices likely has a power outage based on the downstream outage prediction information; and predicting whether each protective device is in an open or closed state based on the downstream and upstream outage prediction information so that more than one open protective device can be identified when more than one fault occurs in different parts of the electrical distribution system.

According to an embodiment of a non-transitory computer readable medium storing a computer program operable to estimate outage scope for the electrical distribution system, the computer program includes program instructions to generate downstream outage prediction information indicating whether any service area protected by one of the terminal protective devices likely has a power outage based on reported outage information. The computer program also includes program instructions to generate upstream outage prediction information indicating whether any service area protected by one of the non-terminal protective devices likely has a power outage based on the downstream outage prediction information. The computer program further includes program instructions to predict whether each protective device is in an open or closed state based on the downstream and upstream outage prediction information so that more than one open protective device can be identified when more than one fault occurs in different parts of the electrical distribution system.

According to an embodiment of a computer system in communication with the electrical distribution system, the computer system includes a processing circuit operable to generate downstream outage prediction information indicating whether any service area protected by one of the terminal protective devices likely has a power outage based on reported outage information. The processing circuit is further operable to generate upstream outage prediction information indicating whether any service area protected by one of the non-terminal protective devices likely has a power outage based on the downstream outage prediction information. The processing circuit is also operable to predict whether each protective device is in an open or closed state based on the downstream and upstream outage prediction information so that more than one open protective device can be identified when more than one fault occurs in different parts of the electrical distribution system.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference numerals designate corresponding parts. In the drawings:

FIG. 1 illustrates a schematic block diagram of an electrical distribution system and an outage restoration management system included in or associated with the distribution system.

FIG. 2 illustrates a flow diagram of an embodiment of a method of estimating outage scope for an electrical distribution system.

### DETAILED DESCRIPTION

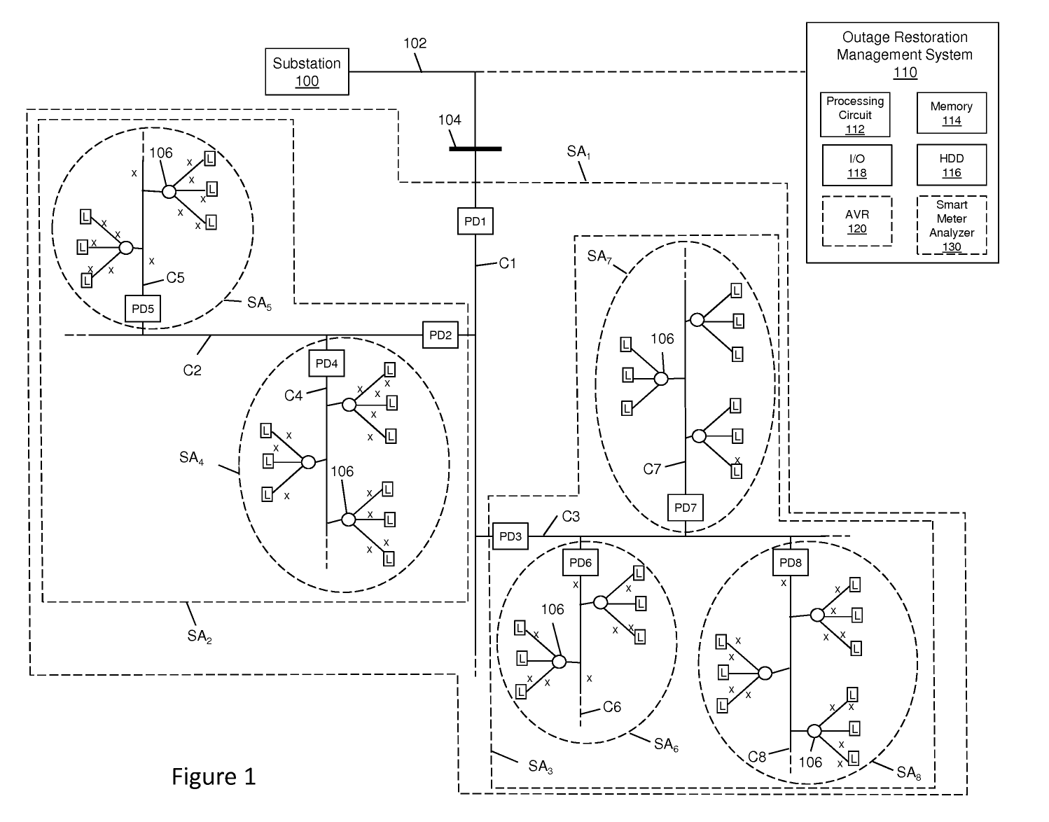

FIG. 1 illustrates a non-limiting exemplary embodiment of an electrical distribution system which includes a plurality of distribution circuits C1 through C8 which distribute power from a substation 100 to a plurality of loads L downstream of the substation 100 (not all distribution circuits are shown in FIG. 1 for ease of illustration). The term ‘downstream’ as used herein refers to the direction of normal power flow within the electrical distribution system. For example, distribution circuits C1, C2 and C3 are downstream of the substation 100, distribution circuits C4, C5, C6, C7, and C8 are downstream of distribution circuits C1, C2 and C3, and the loads L are downstream of distribution circuits C4, C5, C6, C7, and C8. Conversely, distribution circuits C4, C5, C6, C7, and C8 are upstream of the loads and distribution circuits C1, C2 and C3 are upstream of distribution circuits C4, C5, C6, C7, and C8.

The substation 100 receives power from one or more transmission or subtransmission lines (not shown) at a corresponding transmission or subtransmission voltage level and provides that power to one or more main distribution feeders 102 originating from the substation 100. Distribution circuits C1, C2 and C3 of the electrical distribution system can emanate radially from the substation 100 to distribute power, or can be configured in loops. In either case, distribution circuits C1, C2 and C3 are typically three-phase circuits, but can be any desired phase. Primary distribution circuit C1 of the electrical distribution system can be connected to the main distribution feeder 102 originating from the substation 100 by, e.g., a circuit bus 104.

Each distribution circuit C1 through C8 is connected to the electrical distribution system through a respective protective device PD1 through PD8. Some of the protective devices (PD4, PD5, PD6, PD7 and PD8 in FIG. 1) are terminal protective devices in that no other protective device is downstream of the terminal protective devices, i.e., there is no other protective device between a terminal protective device and the loads protected by that terminal protective device. Terminal protective devices PD4, PD5, PD6, PD7 and PD8 are at the edge of the electrical distribution system near the loads. The remainder of the protective devices (PD1, PD2 and PD3 in FIG. 1) are non-terminal protective devices meaning that one or more other protective devices are downstream of the non-terminal protective devices. For example in FIG. 1, non-terminal protective devices PD2 and PD3 and terminal protective devices PD4, PD5, PD6, PD7 and PD8 are downstream of non-terminal protective device PD1, terminal protective devices PD4 and PD5 are downstream of non-terminal protective device PD2, no protective devices are downstream of terminal protective devices PD4 and PD5, etc.

Distribution circuits C1, C2 and C3 can be connected to the electrical distribution system through a respective circuit breaker or recloser PD1, PD2 and PD3. Circuit breaker protective devices carry and interrupt normal load current, and interrupt short-circuit (fault) current. Recloser protective devices are similar in function to circuit breakers, but can also reclose after opening, open again, and reclose again, repeating this cycle a predetermined number of times until locking out. Once set in the open state, circuit breaker and recloser protective devices typically must be manually reset to the closed state by a service crew in order to reenergize the corresponding feeder.

Branching from distribution circuits C1, C2 and C3 are distribution circuits C4, C5, C6, C7, and C8. Distribution circuits C4, C5, C6, C7, and C8 may be three-phase, two-phase (two phases of the three-phase feeder with or without a neutral), or single-phase (one phase from the single phase feeder and a neutral). Distribution circuits C4, C5, C6, C7, and C8 energize service transformers 106, which in turn lower the voltage from the distribution voltage to the utilization or customer voltage, e.g., 120/240 volt two-leg service. Each distribution circuit C4, C5, C6, C7, and C8 is connected to one of distribution circuits C1, C2 and C3 through a respective terminal protective device PD4, PD5, PD6, PD7, and PD8 such as a fuse. Fuse protective devices can carry a defined load current without deterioration and interrupt a defined short-circuit current. Fuse protective devices prevent faulted downstream distribution circuits from causing interruption upstream.

An outage management restoration system 110 monitors the electrical distribution system for outages and estimates outage scope. The outage management restoration system 110 can be connected to the electrical distribution system via a wired or wireless connection as indicated by the dashed line connection shown in FIG. 1. The outage management restoration system 110 includes a processing circuit 112 which can include digital and/or analog circuitry such as one or more controllers, processors, ASICs (application-specific integrated circuits), etc. for executing program code which estimates outage scope in the electrical distribution system. The outage management restoration system 110 further includes memory 114 such as DRAM (dynamic random access memory) and an HDD (hard disk drive) 116 for storing the program code and related data processed and accessed by the processing circuit 112 during execution of the program code. The outage management restoration system 110 also includes I/O (input/output) circuitry 118 for sending and receiving information. An AVR (automated voice response) system 120 included in or associated with the outage management restoration system 110 interacts with humans through the use of voice and DTMF (dual-tone multi-frequency signaling) tones input via keypad. The AVR system 120 provides customer outage reporting information to the outage management restoration system 110 for use in estimating outage scope within the electrical distribution system as described later herein. A smart meter analyzer 130 included in or associated with the outage management restoration system 110 analyzes and reports on information received from smart meters located in the electrical distribution system, for use by the outage management restoration system 110 in estimating outage scope within the distribution system also as described later herein.

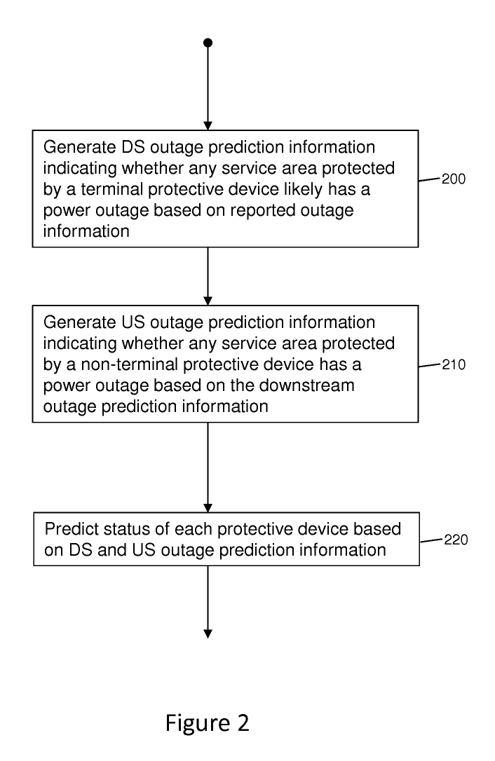

FIG. 2 illustrates an embodiment of a method of estimating outage scope for the electrical distribution system. The method includes generating downstream (DS) outage prediction information indicating whether any service area protected by terminal protective devices PD4, PD5, PD6, PD7 and PD8 likely has a power outage based on reported outage information (Step 200). This includes downstream service areas SA₄, SA₅, SA₆, SA₇ and SA₈ in FIG. 1. The method further includes generating upstream (US) outage prediction information indicating whether any service area protected by non-terminal protective devices PD1, PD2 and PD3 likely has a power outage based on the downstream outage prediction information (Step 210). The service area protected by the x^{th} non-terminal protective device includes the service areas protected by any terminal and/or non-terminal protective devices downstream of the x^{th} non-terminal protective device. Particularly, SA₁ includes SA₂ and SA₃, SA₂ includes SA₄ and SA₅, and SA₃ includes SA₆, SA₇ and SA₈ in FIG. 1.

The method of estimating outage scope for the electrical distribution system continues with predicting whether each protective device PD1, PD2, PD3, PD4, PD5, PD6, PD7 and PD8 is in an open or closed state based on the downstream and upstream outage prediction information so that more than one open protective device can be identified when more than one fault occurs in different parts of the electrical distribution system (Step 220). The outage scope estimation method can handle both single and simultaneous multiple outages by identifying more than one protective device for servicing. The outage scope estimation method can be implemented by the processing circuit 112 included in the outage management restoration system 110, by executing program instructions of a computer program stored in the HDD 116 and loaded into memory 114 which perform the steps described above upon execution. Various embodiments of the outage scope estimation method are described next.

According to one embodiment of generating the downstream outage prediction information, the processing circuit 112 of the outage management restoration system 110 determines whether call volume received for each service area SAₓ protected by a terminal protective device PD4, PD5, PD6, PD7 and PD8 exceeds a predetermined threshold. The predetermined threshold is selected so that a sufficient number of calls must be received before treating one or more of these service areas as having an outage. The processing circuit 112 indicates whether the service area SAₓ protected by any of terminal protective devices PD4, PD5, PD6, PD7 and PD8 is likely to have a power outage based on whether the call volume for the corresponding service area exceeds the predetermined threshold. The processing circuit 112 can determine whether call volume received for each service area SAₓ protected by a terminal protective device PD4, PD5, PD6, PD7 and PD8 exceeds the predetermined threshold by setting the predetermined threshold based on a cumulative probability distribution function (CDF). The CDF describes the probability a power outage occurred in each service area SAₓ protected by a terminal protective device PD4, PD5, PD6, PD7 and PD8 given the probability a customer places a call when a power outage occurs and the probability a customer does not place a call when a power outage occurs. The processing circuit 112 compares the call volume received for each service area SAₓ protected by a terminal protective device PD4, PD5, PD6, PD7 and PD8 to the predetermined threshold to determine whether the threshold is exceeded.

The CDF embodiment is described next in more detail, where the term ‘downstream scope’ refers to the service area SAₓ protected by a terminal protective device PD4, PD5, PD6, PD7 and PD8, the term ‘scope (outage) status’ refers to whether an entire scope is in an outage, and the term ‘upstream scope’ refers to the service area SAₓ protected by a non-terminal protective device PD1, PD2 and PD3. In FIG. 1, service areas SA₄ through SA₈ correspond to downstream scopes S4 through S8 and service areas SA₁ through SA₃ correspond to upstream scopes S1 through S3. With this understanding, the scope outage status for each downstream scope is evaluated based on call volume reported, e.g., by the AVR 120, for the respective downstream scopes.

If a certain number of trouble calls (n_{C}≧1) are received for a particular downstream scope, the cumulative binomial probability (Pᵣ) of receiving n_{C} trouble calls out of N customers for that downstream scope is calculated as given by:

$$f ( {n}_{C} , N , p ) = {P}_{r} ( n \leq {n}_{C} ) = {\sum }_{n = 0}^{{n}_{C}} ( \begin{matrix}N \\ n\end{matrix} ) {{p}^{n} ( 1 - p )}^{N - n} = {\sum }_{n = 0}^{{n}_{C}} \frac{N !}{n ! ( N - n ) !} {{p}^{n} ( 1 - p )}^{N - n} \qquad ( 1 )$$

where N is the total number of customers in the downstream scope under consideration, n_{c} is the number of received trouble calls for the downstream scope, p is the probability of a customer making a trouble call when an outage occurs, and 1−p is the probability of a customer not making a trouble call when an outage occurs.

If the calculated probability value is higher than a predefined threshold, the downstream scope is deemed to have an outage. Otherwise, if the probability is lower than the predefined threshold, it is reasonable to conclude that the downstream scope does not have an outage. For example, customers who make trouble calls may experience an outage caused by an isolated problem at their location instead of the corresponding terminal protective device actually being open. In the case smart meters are available, e.g., as part of the loads L, the scope (outage) status can be further verified by on-demand polling of the smart meters located in the service area in question to check the customer energized status for that downstream scope. In one embodiment, this involves issuing a command to the smart meters located in the service area for which the call volume does not exceed the predetermined threshold and indicating whether the service area is likely to have a power outage based on whether a response message is received from the smart meters. In the case of no (zero) customer calls being received from a particular scope while one (or more) of parallel scopes is identified to have an outage, the smart meter on-demand polling results can be used similarly to check the customer energized status for the scope of interest. In this case, smart meters can be used to help determine whether an outage has occurred.

Table 1 below lists the number of trouble calls received and the corresponding cumulative binomial probability given by equation (1) for the following parameters: N=100; p=0.1; and (1−p)=0.9.

TABLE 1
Number of trouble calls and corresponding cumulative
binomial probability

| Number of Trouble Calls n_{c} | Cumulative Probability |
|---|---|
| 0 | 2.65614E−05 |
| 1 | 0.000321688 |
| 2 | 0.001944885 |
| 3 | 0.007836487 |
| 4 | 0.023711083 |
| 5 | 0.057576886 |
| 6 | 0.117155615 |
| 7 | 0.206050862 |
| 8 | 0.320873888 |
| 9 | 0.451290165 |

If the threshold is predefined as 0.05 and the number of received calls from the scope is equal to or greater than 5, the scope is concluded to be in an outage caused by the corresponding terminal protective device opening. Accordingly, the downstream outage prediction information or downstream scope (outage) status (S_{downstream}) is set to a binary value of 1 for the scope to indicate an outage and 0 otherwise as given by:

$${S}_{downstream} = \{ \begin{matrix}1 & if f ( {n}_{C} , N , p ) \geq threshold \\ 0 & otherwise\end{matrix} \qquad ( 2 )$$

Returning to the exemplary embodiment illustrated in FIG. 1, four of the five downstream scopes (corresponding to service areas SA₄, SA₅, SA₆, and SA₈) may receive call volume which exceeds the predetermined threshold. Individual trouble call locations are shown with an ‘x’ in FIG. 1. However, only protective devices PD2, PD6 and PD8 have actually opened in this example responsive to different faults. The call volume from downstream service area SA₇ is below the predetermined threshold, and the call volume for the other downstream service areas SA₄, SA₅, SA₆, and SA₈ is above the predetermined threshold.

In accordance with equation (1), the following downstream scope (outage) statuses therefore are assigned in this purely illustrative example: S4_{downstream}=1; S5_{downstream}=1; S6_{downstream}=1; S7_{downstream}=0; and S8_{downstream}=1 where S4_{downstream} corresponds to downstream service area SA₄, S5_{downstream} corresponds to downstream service area SA₅, etc. The predetermined threshold can be determined based on heuristic data collected for each downstream service area, or based on other data indicating how many calls are needed to reliably indicate a downstream service area has an outage.

According to another embodiment of generating the downstream outage prediction information, the processing circuit 112 of the outage management restoration system 110 processes smart meter reporting information to estimate the outage status of the downstream scopes. To this end, the processing circuit 112 determines whether smart meter reporting for each downstream service area protected by terminal protective devices PD4, PD5, PD6, PD7 and PD8 indicates a power outage in one or more of these service areas. The processing circuit 112 indicates whether a downstream service area protected by terminal protective devices PD4, PD5, PD6, PD7 and PD8 is likely to have a power outage based on the smart meter reporting. For example, the smart meter reporting can indicate whether customer locations within a particular downstream service area are energized. If enough locations are de-energized, e.g., as indicated by a low or high volume of smart meter reporting, the scope (outage) status of the affected downstream scope can be set to a binary value of 1 to indicate a power outage for that scope. Otherwise, a binary value of 0 is assigned to indicate no power outage for the downstream scope under consideration.

After the downstream outage prediction information is generated for each downstream scope as described above, the processing circuit 112 continues with the outage scope estimation process by generating upstream outage prediction information based on the previously calculated downstream outage prediction information. The upstream outage prediction information (Sᵤₚₛₜᵣₑₐₘ) indicates whether any upstream service area SAₓ protected by non-terminal protective devices PD1, PD2 and PD3 likely has a power outage and is calculated for each upstream scope as given by:

$${S}_{upstream} = {\prod }_{i = 1}^{m} {Si}_{downstream} \qquad ( 3 )$$

where m corresponds to the total number of downstream scopes. Again returning to the exemplary embodiment illustrated in FIG. 1, upstream outage prediction information is calculated using equation (3) for the three upstream scopes corresponding to upstream service areas SA₁, SA₂ and SA₃. For the example above where S4_{downstream}=1, S5_{downstream}=1, S6_{downstream}=1, S7_{downstream=}0, and S8_{downstream}=1, the upstream outage prediction information for the three upstream scopes is calculated as follows:

S2ᵤₚₛₜᵣₑₐₘ=S4_{downstream}*S5_{downstream}=1;

S3ᵤₚₛₜᵣₑₐₘ=S6_{downstream}*S7_{downstream}*S8_{downstream}=0;

S1ᵤₚₛₜᵣₑₐₘ=S2ᵤₚₛₜᵣₑₐₘ*S3ᵤₚₛₜᵣₑₐₘ=0.

In this case, the binary values assigned to each downstream service area protected by a terminal protective device are multiplied to yield a binary value indicating the state of the corresponding upstream scope. For example with regard to FIG. 1, distribution circuits C5 and C4 are connected to distribution circuit C2 which corresponds to upstream scope S2 (service area SA₂). The upstream outage prediction information for upstream scope S2 is therefore calculated by multiplying S4_{downstream} (the downstream outage prediction information for scope S4 supplied by distribution circuit C4) and S5_{downstream} (the downstream outage prediction information for scope S5 supplied by distribution circuit C5). A similar calculation is performed for upstream scope S3 (supplied by distribution circuit C3) by multiplying S6_{downstream} (the downstream outage prediction information for scope S6 supplied by distribution circuit C6), S7_{downstream} downstream (the downstream outage prediction information for scope S7 supplied by distribution circuit C7) and S8_{downstream} (the downstream outage prediction information for scope S8 supplied by distribution circuit C8). The remaining distribution circuit C1 corresponds to service area SA₁ (upstream scope S1), which includes service area SA₂ supplied by distribution circuit C2 and service area SA₃ supplied by distribution circuit C3. The upstream outage prediction information for upstream scope S1 is calculated in accordance with equation (3) by multiplying S2ᵤₚₛₜᵣₑₐₘ and S3ᵤₚₛₜᵣₑₐₘ to yield S1ᵤₚₛₜᵣₑₐₘ for or service area SA_{1.}

In general, the processing circuit 112 multiplies the binary values assigned to a group of the service areas each protected by one of the terminal protective devices (S2ᵤₚₛₜᵣₑₐₘ=S4_{downstream}*S5_{downstream} and S3ᵤₚₛₜᵣₑₐₘ=S6_{downstream}*S7_{downstream}*S8_{downstream} in the example above) to yield a binary value indicating whether the corresponding upstream service area including the group of service areas each protected by one of the terminal protective devices has a power outage (SA₂ and SA₃ in the example above). The processing circuit 112 also multiplies the binary values assigned to a group of the upstream service areas collectively corresponding to a larger service area (S1ᵤₚₛₜᵣₑₐₘ=S2ᵤₚₛₜᵣₑₐₘ*S3ᵤₚₛₜᵣₑₐₘ in the example above) to yield a binary value indicating whether that group of upstream service areas has a power outage (SA₁ in the example above).

After the downstream and upstream outage prediction information is generated, the processing circuit 112 continues with the outage scope estimation process by predicting whether each protective device PD1 through PD8 is in an open or closed state based on the downstream and upstream outage prediction information. The protective device states are predicted so that more than one open protective device can be identified when more than one fault occurs in different parts of the electrical distribution system. In one embodiment, the state (D) of each protective device PD1 through PD8 is predicted based on the binary value assigned to the service area protected by that protective device and the binary value assigned to each service area upstream of that protective device as given by:

$$Di = {Si}_{downstream} {\prod }_{j = 1}^{k} ( 1 - {Sj}_{upstream} ) = \{ \begin{matrix}0 & protective device in close status \\ 1 & protective device in open status\end{matrix} \qquad ( 4 )$$

where k corresponds to the number of protective devices under analysis.

The state of each protective device PD1 through PD8 is determined based on its downstream scope outage and all upstream scope outage information. For example, the state indicates one of the protective devices PD1 through PD8 is open when the binary value assigned to the service area protected by that protective device indicates a power outage has occurred (is a logic one in the example above) and the binary value assigned to each service area upstream of that protective device indicates each of the upstream service areas does not have a power outage (is a logic zero in the example above). Otherwise, the state indicates the protective device is closed either when the binary value assigned to the service area protected by that protective device indicates a power outage has not occurred (is a logic zero in the example above) or the binary value assigned to each service area upstream of that protective device indicates each of the upstream service areas has a power outage (is a logic one in the example above). Again using the illustrative fault example previously described herein with regard to the electrical distribution system of FIG. 1, the state (D) of each protective device (PDX) included in the distribution network can be predicted as follows:

D1=S1ᵤₚₛₜᵣₑₐₘ=0

D2=S2ᵤₚₛₜᵣₑₐₘ*(1−S1ᵤₚₛₜᵣₑₐₘ)=1

D3=S3ᵤₚₛₜᵣₑₐₘ*(1−S1ᵤₚₛₜᵣₑₐₘ)=0

D4=S4_{downstream}*(1−S2ᵤₚₛₜᵣₑₐₘ)*(1−S1ᵤₚₛₜᵣₑₐₘ)=0

D5=S5_{downstream}*(1−S2ᵤₚₛₜᵣₑₐₘ)*(1−S1ᵤₚₛₜᵣₑₐₘ)=0

D6=S6_{downstream}*(1−S3ᵤₚₛₜᵣₑₐₘ)*(1−S1ᵤₚₛₜᵣₑₐₘ)=1

D7=S7_{downstream}*(1−S3ᵤₚₛₜᵣₑₐₘ)*(1−S1ᵤₚₛₜᵣₑₐₘ)=0

D8=S8_{downstream}*(1−S3ᵤₚₛₜᵣₑₐₘ)*(1−S1ᵤₚₛₜᵣₑₐₘ)=1

After execution of the above steps, each open protective device is identified and the outage scopes determined. For the example circuit given above, there are three outage scopes (S2, S6, S8), and three protective devices PD2, PD6 and PD8 in the open state. This example demonstrates that the outage scope estimation method described herein can provide outage scope and open device information for both single and multiple outages within an electrical distribution system. Service crews can be dispatched to service each protective device of the electrical distribution system having a predicted open state.

Terms such as “first”, “second”, and the like, are used to describe various elements, regions, sections, etc. and are not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of estimating outage scope for an electrical distribution system including a plurality of distribution circuits connected to the electrical distribution system through protective devices operable to isolate the corresponding distribution circuits from the remainder of the electrical distribution system responsive to a fault, some of the protective devices being terminal protective devices in that no other protective device is downstream of the terminal protective devices, the remainder of the protective devices being non-terminal protective devices in that one or more other protective devices are downstream of the non-terminal protective devices, the method comprising:
generating downstream outage prediction information indicating whether any service area protected by one of the terminal protective devices likely has a power outage based on reported outage information;
generating upstream outage prediction information indicating whether any service area protected by one of the non-terminal protective devices likely has a power outage based on the downstream outage prediction information; and
predicting whether each protective device is in an open or closed state based on the downstream and upstream outage prediction information so that more than one open protective device can be identified when more than one fault occurs in different parts of the electrical distribution system.

2. A method according to claim 1, wherein generating the downstream outage prediction information based on the reported outage information comprises:
determining whether call volume received for each service area protected by the terminal protective devices exceeds a predetermined threshold; and
indicating whether the service area protected by any of the terminal protective devices is likely to have a power outage based on whether the call volume for the corresponding service area exceeds the predetermined threshold.

3. A method according to claim 2, wherein determining whether call volume received for each service area protected by the terminal protective devices exceeds a predetermined threshold comprises:
setting the predetermined threshold based on a cumulative probability distribution function describing the probability a power outage occurred in each service area protected by the terminal protective devices given the probability a customer places a call when a power outage occurs in the corresponding service area and the probability a customer does not place a call when a power outage occurs in the corresponding service area; and
comparing the call volume received for each service area to the predetermined threshold.

4. A method according to claim 2, wherein the predetermined threshold is set based on heuristic data collected for each service area protected by the terminal protective devices.

5. A method according to claim 2, further comprising:
issuing a command to a plurality of smart meters located in a service area for which the call volume does not exceed the predetermined threshold; and
indicating whether a service area protected by any of the terminal protective devices is likely to have a power outage based on whether a response message is received from the smart meters.

6. A method according to claim 1, wherein generating the downstream outage prediction information based on the reported outage information comprises:
determining whether smart meter reporting for each service area protected by the terminal protective devices indicates a power outage in one or more of these service areas; and
indicating whether a service area protected by any of the terminal protective devices is likely to have a power outage based on the smart meter reporting.

7. A method according to claim 1, wherein the downstream outage prediction information comprises a binary value assigned to each service area protected by one of the terminal protective devices indicating whether that service area is likely to have a power outage.

8. A method according to claim 7, wherein generating the upstream outage prediction information based on the downstream outage prediction information comprises:
multiplying the binary values assigned to a group of the service areas each protected by one of the terminal protective devices to yield a binary value indicating whether an upstream service area including the group of service areas each protected by one of the terminal protective devices has a power outage; and
multiplying the binary values assigned to a group of the upstream service areas collectively corresponding to a larger service area to yield a binary value indicating whether the group of upstream service areas has a power outage.

9. A method according to claim 8, wherein the state of each protective device is predicted based on the binary value assigned to the service area protected by that protective device and the binary value assigned to each service area upstream of that protective device.

10. A method according to claim 9, wherein the state of one of the protective devices indicates that protective device is open when the binary value assigned to the service area protected by that protective device indicates a power outage has occurred and the binary value assigned to each service area upstream of that protective device indicates each of the upstream service areas does not have a power outage.

11. A method according to claim 9, wherein the state of one of the protective devices indicates that protective device is closed either when the binary value assigned to the service area protected by that protective device indicates a power outage has not occurred or the binary value assigned to each service area upstream of that protective device indicates each of the upstream service areas has a power outage.

12. A non-transitory computer readable medium storing a computer program operable to estimate outage scope for an electrical distribution system including a plurality of distribution circuits connected to the electrical distribution system through protective devices operable to isolate the corresponding distribution circuits from the remainder of the electrical distribution system responsive to a fault, some of the protective devices being terminal protective devices in that no other protective device is downstream of the terminal protective devices, the remainder of the protective devices being non-terminal protective devices in that one or more other protective devices are downstream of the non-terminal protective devices, the computer program comprising:
program instructions to generate downstream outage prediction information indicating whether any service area protected by one of the terminal protective devices likely has a power outage based on reported outage information;
program instructions to generate upstream outage prediction information indicating whether any service area protected by one of the non-terminal protective devices likely has a power outage based on the downstream outage prediction information; and
program instructions to predict whether each protective device is in an open or closed state based on the downstream and upstream outage prediction information so that more than one open protective device can be identified when more than one fault occurs in different parts of the electrical distribution system.

13. A computer system in communication with an electrical distribution system including a plurality of distribution circuits connected to the electrical distribution system through protective devices operable to isolate the corresponding distribution circuits from the remainder of the electrical distribution system responsive to a fault, some of the protective devices being terminal protective devices in that no other protective device is downstream of the terminal protective devices, the remainder of the protective devices being non-terminal protective devices in that one or more other protective devices are downstream of the non-terminal protective devices, the computer system comprising a processing circuit operable to:
generate downstream outage prediction information indicating whether any service area protected by one of the terminal protective devices likely has a power outage based on reported outage information;
generate upstream outage prediction information indicating whether any service area protected by one of the non-terminal protective devices likely has a power outage based on the downstream outage prediction information; and
predict whether each protective device is in an open or closed state based on the downstream and upstream outage prediction information so that more than one open protective device can be identified when more than one fault occurs in different parts of the electrical distribution system.

14. A computer system according to claim 13, wherein the processing circuit is operable to determine whether call volume received for each service area protected by the terminal protective devices exceeds a predetermined threshold and indicate whether the service area protected by any of the terminal protective devices is likely to have a power outage based on whether the call volume for the corresponding service area exceeds the predetermined threshold.

15. A computer system according to claim 14, wherein the processing circuit is operable to set the predetermined threshold based on a cumulative probability distribution function describing the probability a power outage occurred in each service area protected by the terminal protective devices given the probability a customer places a call when a power outage occurs in the corresponding service area and the probability a customer does not place a call when a power outage occurs in the corresponding service area, and compare the call volume received for each service area to the predetermined threshold.

16. A computer system according to claim 14, wherein the processing circuit is operable to issue a command to a plurality of smart meters located in a service area for which the call volume does not exceed the predetermined threshold and indicate whether a service area protected by any of the terminal protective devices is likely to have a power outage based on whether a response message is received from the smart meters.

17. A computer system according to claim 13, wherein the processing circuit is operable to determine whether smart meter reporting for each service area protected by the terminal protective devices indicates a power outage in one or more of these service areas and indicate whether a service area protected by any of the terminal protective devices is likely to have a power outage based on the smart meter reporting.

18. A computer system according to claim 13, wherein the downstream outage prediction information comprises a binary value assigned to each service area protected by one of the terminal protective devices indicating whether that service area is likely to have a power outage.

19. A computer system according to claim 18, wherein the processing circuit is operable to multiply the binary values assigned to a group of the service areas each protected by one of the terminal protective devices to yield a binary value indicating whether an upstream service area including the group of service areas each protected by one of the terminal protective devices has a power outage, and to multiply the binary values assigned to a group of the upstream service areas collectively corresponding to a larger service area to yield a binary value indicating whether the group of upstream service areas has a power outage.

20. A computer system according to claim 19, wherein the processing circuit is operable to predict the state of each protective device based on the binary value assigned to the service area protected by that protective device and the binary value assigned to each service area upstream of that protective device.

21. A computer system according to claim 20, wherein the processing circuit is operable to indicate one of the protective devices is open when the binary value assigned to the service area protected by that protective device indicates a power outage has occurred and the binary value assigned to each service area upstream of that protective device indicates each of the upstream service areas does not have a power outage.

22. A computer system according to claim 20, wherein the processing circuit is operable to indicate one of the protective devices is closed either when the binary value assigned to the service area protected by that protective device indicates a power outage has not occurred or the binary value assigned to each service area upstream of that protective device indicates each of the upstream service areas has a power outage.
